(19) United States
(12) Patent Application Publication
(10) Pub. No.: US 2008/0258179 A1
(43) Pub. Date: Oct. 23, 2008

(54) Hybrid molecular electronic device for switching, memory, and sensor applications, and method of fabricating same

(75) Inventors: James M. Tour, Bellaire, TX (US); Harry F. Pang, Houston, TX (US); Jianli He, Santa Barbara, CA (US)

Correspondence Address: WINSTEAD PC, P.O. BOX 50784, DALLAS, TX, 75201, US

(73) Assignee: William Marsh Rice University, Houston, TX (US)

(21) Appl. No.: 11/157,391

(22) Filed: Jun. 21, 2005

Related U.S. Application Data
(60) Provisional application No. 60/581,409, filed on Jun. 21, 2004.
(60) Provisional application No. 60/581,492, filed on Jun. 21, 2004.

(51) Int. Cl. H01L 29/78; H01L 21/336

(52) U.S. Cl. 257/253; 438/49; 257/E29.255; 257/E21.409

(57) ABSTRACT

A hybrid molecular electronic device having switching, memory, and sensor application is disclosed. In one embodiment, the device resembles a conventional field-effect transistor (FET) formed on a silicon-on-insulator (SOI) substrate. Source and drain doped regions are formed in an upper surface of the SOI substrate, and a metallization layer which can serve as a gate contact is formed on a lower surface of the SOI substrate. A channel region spanning between the doped source and drain regions is left exposed, in order that a monolayer of molecules may be formed therein. Upon application of appropriate gating voltages to the gate contact, conduction between the source and drain regions can be modulated, possibly as a result of the reduction and oxidation of the molecules grafted to the gate region.

### RELATED APPLICATION DATA

This application claims the priority of prior U.S. provisional application Ser. No. 60/581,409 filed on Jun. 21, 2004, which application is hereby incorporated by reference herein in its entirety. This application also claims the priority of prior U.S. provisional application Ser. No. 60/581,492 filed on Jun. 21, 2004, which application is also hereby incorporated by reference herein in its entirety.

### STATEMENT REGARDING FEDERALLY SPONSORED RESEARCH OR DEVELOPMENT

The invention was made with support from Defense Advanced Research Projects Agency (DARPA) administered through the Office of Naval Research (ONR), Grants Nos. N00014-01-1-0657 and N00014-04-1-0765.

### FIELD OF THE INVENTION

The present invention relates generally to the field of molecular electronics, and more particularly relates to a hybrid electronic device incorporating solid-state and molecular components.

### BACKGROUND OF THE INVENTION

Recent advances in “wet” surface chemistry offer an increasingly sophisticated range of techniques for self-orienting molecular chemisorption on a wide variety of materials. See, e.g., Ullman, A., Chem Rev. 1996, 96, 1533; see also, Buriak, J. M., Chem. Rev. 2002, 102, 1271; Seker, F.; Meeker, K.; Kuech, T. F.; Ellis, A. B.; Chem. Rev., 2000, 100, 2505. Such techniques expand the broad, general applicability of synthetic chemistry to heterogeneous phase and have improved the prospects for “bottom up” fabrication strategies in nanotechnology. Specifically, work related to the construction of post-CMOS (complementary metal-oxide semiconductor) hybrid electronic devices using chemical techniques and molecular components to augment traditional fabrication techniques requires more control at the molecule/contact interfaces.

In many experimental molecular electronic systems, molecules assembled between bulk metallic electrodes have chemical contacts that are highly polar, such as the sulfur-metal bond. This allows for undesired interfacial capacitance, possible electrochemical activity at the bond interface, and generally causes the molecule in the electrode gap to behave as a tunneling barrier. If the electronic properties of various chemical substituents on molecular devices are to be more fully exploited, a less polar, more electronically continuous chemical interface is required.

In particular, it is believed that a direct covalent bond, allowing stronger electronic coupling between the energy bands of a bulk contact and the frontier orbitals of a conjugated organic molecule, would allow for a greater measure of synthetic variation in device properties and make contact effects less dominant.

Furthermore, once the undesirable contact effects have been overcome, it is believed that a hybrid molecular electronic device can be constructed which can find various applications including those of switching, memory, and sensing applications.

### SUMMARY OF THE INVENTION

The present invention is directed to a hybrid molecular electronic device. In one embodiment, a device in accordance with the present invention structurally resembles a conventional field effect transistor (FET), but differs in that the surface area between the source and drain is not protected with an insulating dielectric but is left open for attachment of molecules. In a preferred embodiment, the gate is moved from the top surface to the back of the wafer, although it is contemplated that the position of the gate is not critical, and that traditional architectures with the gate on the top side may be employed so long as the molecules can be grafted to the channel area. The device can be used as a switching device (i.e, a transistor), a memory element, or as a chemical sensor.

### BRIEF DESCRIPTION OF THE DRAWINGS

The foregoing and other features and aspects of the subject invention will be best understood with reference to a detailed description of specific embodiments of the invention, which follow, when read in conjunction with the accompanying drawing, wherein:

FIG. 1 is a cross section of a hybrid electronic device in accordance with one embodiment of the invention;

FIGS. 2a through 2e illustrate the chemical process of grafting molecules to a surface;

FIGS. 3a through 3h are exemplary candidate molecules for incorporation into the device of FIG. 1;

FIG. 4 is a photomicrograph of a wafer of hybrid electronic devices fabricated in accordance with one embodiment of the invention;

FIGS. 5a and 5b are current-voltage plots of a device in accordance with one embodiment of the invention respectively having molecules grafted to the gate region and molecules removed from the gate region;

FIG. 6 is a current-voltage plot of devices in accordance with one embodiment of the invention for molecule grafting areas of varying dimensions, showing that current scales with grafting area.;

FIG. 6b illustrates a portion of the device 10 utilized to derive the data plotted in FIG. 6, including a portion of the substrate and a molecular monolayer thereon;

FIG. 7 is a current-voltage plot of a device in accordance with one embodiment of the invention showing the effects of varying gating voltages thereon when molecules are grafted over a channel region of the device and when these molecules have been removed from the same device; and

FIG. 8 is a current voltage plot of a device in accordance with one embodiment of the invention showing the effects of molecules being grafted onto a gate portion thereof as compared with such molecules being removed from the gate portion.

### DETAILED DESCRIPTION OF SPECIFIC EMBODIMENTS OF THE INVENTION

In the following description, specific parametric details are set forth, including specific quantities, sizes, and the like, so as to provide a thorough understanding of embodiments of the present invention. However, it will be readily apparent to those of ordinary skill in the art that the present invention may be practiced while deviating to varying extents from specifically detailed parameters. In many cases, details concerning certain features and parameters of the invention have been omitted, inasmuch as such details are not believed to be necessary to obtain a complete understanding of the present invention and are within the skills of persons of ordinary skill in the relevant art.

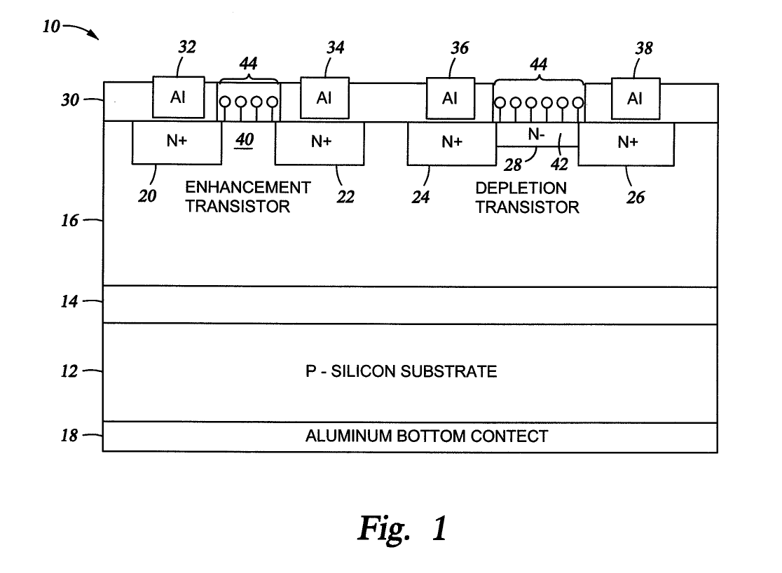

Referring to FIG. 1, there is shown a hybrid molecular-electronic device 10 in accordance with one embodiment of the invention. In the presently disclosed embodiment, device 10 is fabricated on a conventional silicon-on-insulator (SOI) wafer, although it is believed that the present invention is by no means limited to SOI wafers. The SOI wafer in the presently disclosed embodiment consists of a first silicon substrate 12, an insulating layer 14, and a second silicon substrate 16. SOI wafers such as shown in FIG. 1 are well-known and widely used in the semiconductor industry, and are commercially available from various sources.

The SOI substrate can be either p-type or n-type, depending on the majority carrier desired. As would be known by those of ordinary skill in the art, electrical conduction in a p-type substrate is due chiefly due to the movement of positive holes, wherein in an n-type substrate, electrical conduction is due chiefly to the movement of negative electrons. It is very common in semiconductor processing (e.g., complementary metal-oxide semiconductor or CMOS devices) to use both types of majority carriers by creating a “well” of one type in a substrate of the opposite type. Those of ordinary skill in the art having the benefit of the present disclosure will appreciate that the present invention can be practiced in the context of CMOS devices, although for the sake of clarity, the following description is limited to a device in a p-type substrate.

With continued reference to FIG. 1, device 10 further includes a metallization layer 18 on the underside of the SOI wafer, i.e., on the underside of substrate 12. As will hereinafter be described in further detail, metallization layer 18 serves as a contact to allow a potential to be placed on the substrate 12. Formation of metallization layers such as metallization layer 18 shown in FIG. 1 is a common semiconductor fabrication process.

A plurality of doped regions 20, 22, 24, and 26 each having a high concentration of n-type dopant (for example, without limitation, phosphorus, arsenic, or antimony), termed n+, are formed in substrate 16. These doped regions 20-26 are formed using conventional semiconductor fabrication techniques that are well-known and commonly practiced. The steps taken to form regions 20-26, as well as other common semiconductor fabrication techniques referred to herein, implicitly or explicitly, such as photomasking, etching, metallization, formation of oxide layers, metallization layers, and the like, will not be detailed herein, inasmuch as these techniques are abundantly well-known to those of ordinary skill in the art.

As will be hereinafter described, the n+ regions 20-26 can serve as transistor source/drains, and also provide ohmic contacts to the metallization.

Device 10 further comprises an insulating oxide layer 30 on the upper surface of substrate 16. Insulating layer 30 is selectively etched away to allow for the formation of metal (e.g., aluminum) contacts 32, 34, 36, and 38 contacting respective n+ source/drain regions 20, 22, 24, and 26. Insulating layer 30 is further etched away to expose channel regions 40 and 42 between respective source/drain pairs 20, 22 and 24, 26.

An area of lower dopant concentration, termed n−, designated with reference numeral 28 in FIG. 1, is formed to connect the n+ regions 24 and 26. This creates a path of continuity between these source/drain regions 24 and 26. It is contemplated that in one embodiment, the doping of region 28 may be limited to only the surface of substrate 16, resulting in an ultra-shallow channel region.

As thus far described, and as previously noted, device 10 is formed using conventional semiconductor fabrication techniques. To summarize, the fabrication process involves the following steps:

1) Cover the entire silicon-on-insulator (SOI) wafer (substrate 12, oxide layer 14, and substrate 16) with an insulating silicon oxide 30.

2) Open windows in the oxide and create highly doped, conductive pockets (20, 22, 24, and 26) in the silicon substrate 16 to serve as transistor source and drains.

3) Open another window which will allow doping of the same type but at a lower concentration (n− region 28). This will connect source/drain regions 24 and 26.

4) Define metal leads (32, 34, 36, and 38) which contact the source/drain areas and lead to large probe pads.

5) Define windows (channel regions 40 and 42) which stay open and allow molecular assembly after completion of the fabrication process.

6) Place metallization 18 on the wafer backside to contact the substrate.

In accordance with one aspect of the invention, a next step in the formation of device 10 is the grafting of a layer of molecules 44 to the surface of substrate 16 in the channel regions 40 and 42.

It is important to note that the embodiment of the invention shown in FIG. 1 permitted the inventors to rapidly test the concept of gate-property modulation via molecular attachment to the channel. However, it is to be understood that more standard architectures wherein the gate is set atop the channel can also be used so long as there are process steps allowing for attachment of molecules 44 to the channel. That is, those of ordinary skill in the art having the benefit of the present disclosure will appreciate that the present invention can be practiced in the context of more traditional CMOS device architectures.

In the preferred embodiment, grafting of the layer of molecules 44 to substrate 16 is accomplished through spontaneous activation of aryldiazonium salts to assemble covalently bound conjugated molecular layers on substrate 16. See: Stewart, M. P.; Maya, F.; Kosynkin, D. V.; Dirk, S. M.; Stapleton, J. J.; McGuiness, C. L.; Allara, D. L; Tour, J. M. “Direct Covalent Grafting of Conjugated Molecules onto Si, GaAs, and Pd Surfaces from Aryldiazonium Salts,” J. Am. Chem Soc. 2004, 126, 370-378, which is hereby incorporated by reference herein in its entirety. In accordance with one aspect of the invention, molecular layer 44 may be a monolayer, a bilayer, or a multilayer, although a monolayer is the presently preferred embodiment.

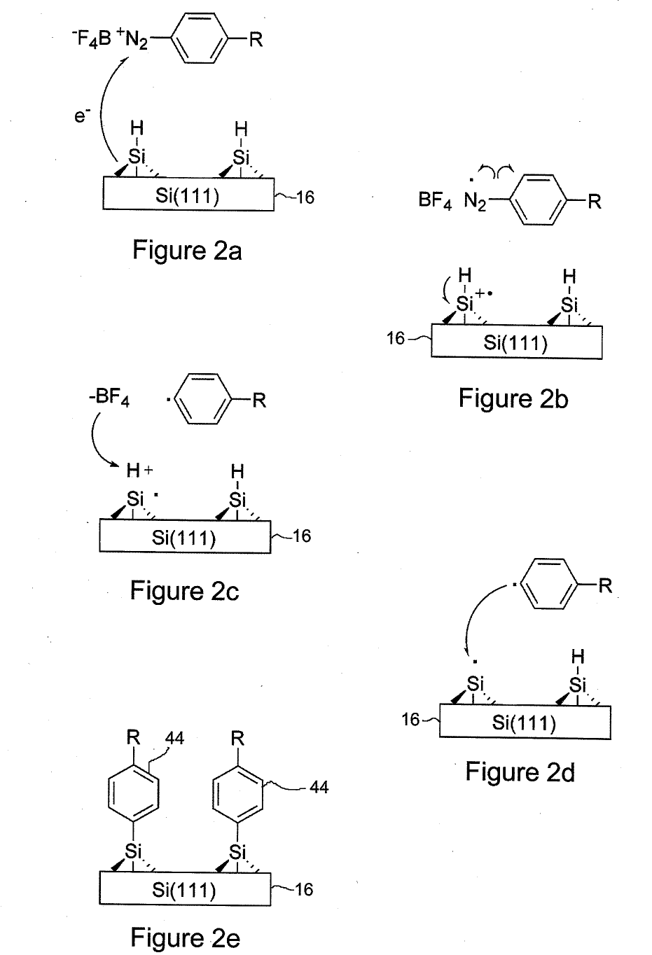

Referring to FIGS. 2a through 2e, the procedure begins with hydride passivation of the silicon surface in channel regions 40 and 42, as shown in FIG. 2a. Thereafter, an electron transfer from the surface of substrate 16, at open circuit potential, generates a diazenyl radial, as shown in FIG. 2b, and then an aryl radical upon loss of N₂, as shown in FIG. 2c. The complementary oxidative process generates a proton, which eliminates as HBF₄, resulting in what is depicted in FIG. 2d. The result, shown in FIG. 2e, is a high-quality monolayer of molecules 44. The reaction has been shown to have a sensitivity to the presence of a radical scavenger such as butylated hydroxytoulene (BHT), added in small amounts to retard the formation of multilayers without preventing the reaction from occurring. Experimental data suggests that a high-quality monolayer of the chemisorbates 44 tends to be complete within approximately two hours under nitrogen atmosphere.

A notable feature of the process described above with reference to FIGS. 2a through 2e is that it is performed at open-circuit potential (OCP), i.e., no externally applied activation potential is applied. This chemistry advantageously has the ability to be applied to devices where electrochemical means of surface activation are either unwieldy or impossible, such as isolated, non-planar, or low-conductive substrates.

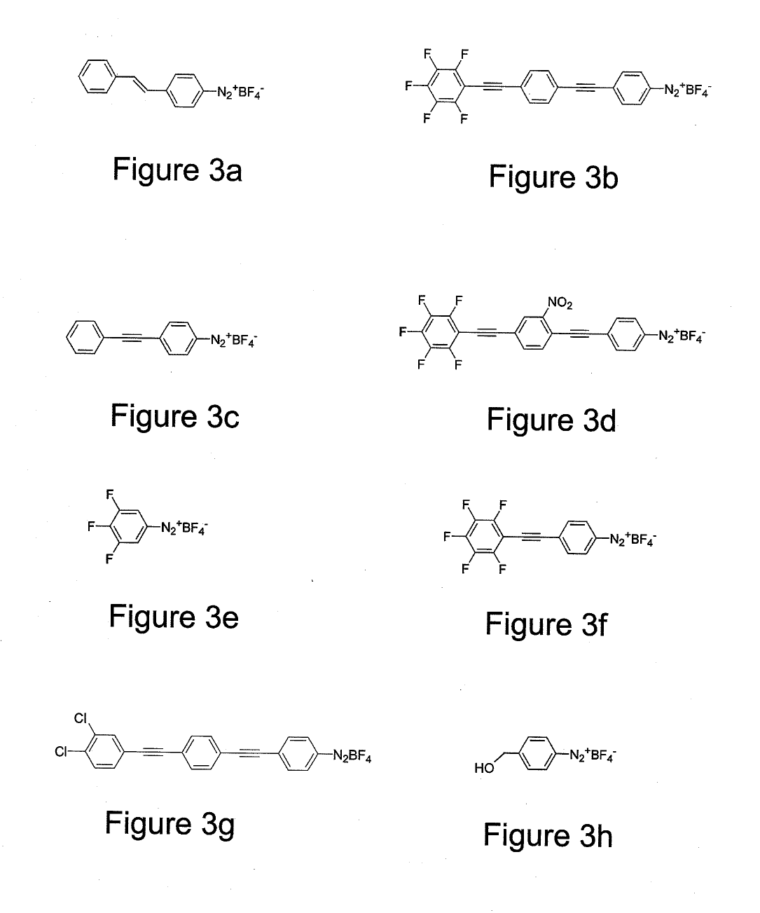

FIGS. 3a through 3h are an exemplary sampling of the sorts of diazonium salts shown to be suitable for the purposes of the present invention. It is to be understood that the invention is by no means limited to those shown in FIG. 3a through 3h. The diazonium molecules are first dissolved in anhydrous CH₃CN. When the device is immersed into the solution, the process as described above leads to formation of the molecular layer.

As shown in FIG. 1, two separate transistor-like devices are shown, a first including source/drain regions 20 and 22 and channel region 40, which is an enhancement mode device, and a second including source/drain regions 24 and 26 and channel region 42, which is a depletion mode device.

The following sets forth the inventors' present best understanding of the mechanisms by which the properties of channels 42 and 44 are modified as a result of the presence of molecules 44: In the depletion mode device, the molecules 44, with the proper gate bias applied to bottom contact 18, are at least partially reduced, gaining electrons. The molecules 44 will remain in this reduced form, even after removal of the gate bias. The negative charge. on the molecules 44 will repel electrons from the n-region 28 at the surface, forming an immobile layer of fixed positive charge. This reduces the cross-sectional area for electron flow between source 24 and drain 26, through channel region 42, and therefore reduces the current between source 24 and drain 26. The application of voltage with the opposite polarity to gate contact 18 will oxidize the molecules 44 and return them to their original state. The removal of the molecular charge also restores the cross-sectional area in channel region 42. The current thus returns to its original magnitude. In some embodiments, the charge state of molecules 44 may be persistent to some extent, such that the device 10 may operate as a non-volatile, or at least semi-non-volatile memory cell. This device 10 can be operated as an n-channel depletion-mode molecular FET (mole-FET). It may be used as a two-level memory device by reading the current to determine if the molecules 44 are either oxidized or reduced. It is contemplated that multiple memory levels are also possible if the molecules 44 can take additional electrons.

The complementary device including source and drain regions 20 and 22 and channel region 40 is similar, but has no n− area corresponding to n− area 28 in the depletion mode device. The n+ source/drain regions 20 and 22 remain separated by the p-type substrate 16, and no current flows between them. By applying the proper gate bias to gate contact 18, the assembled molecules 44 are at least partially oxidized and become positively charged. This attracts electrons to the surface, creating a channel which connects source 20 to drain 22 and allows current flow. The application of voltage with the opposite polarity will reduce molecules 44 and return them to their original state. The device functions like an n-channel enhancement-mode molecular FET, and can serve as a memory similar to the depletion-mode device.

It is contemplated that the mole-FET, both depletion and enhancement modes, may also be used as a chemical sensor. When a molecule to be detected, called the target molecule, reacts with an appropriately-chosen chemically bonded molecule, this reaction removes the bound molecule or alters its reduction/oxidation properties. As with application of a gating voltage to metallization layer 18, this modulation of the reduction/oxidation properties of the molecules 44 results in a corresponding modulation of the conductivity across channel regions. The resulting change in resistance is an indicator of the presence of the target molecule.

It is contemplated, for example, that certain chemical or biological agents may be sensed through the use of saccharides, polypeptides, biotin or oligonucleotides (i.e. DNA) as the grafted molecules. Upon exposure to analytes that are complements to the bonded molecules, such as cell wall saccharides, peptide substrates, biotin-conjugates (avidin), complementary DNA strands, respectively, the oxidation/reduction or electrostatic properties of the grafted molecules will alter, thereby modulating the channel charge or partial charge. This modulation should be detectible via the source-drain-gate electronic characteristics. Those of ordinary skill in the art will appreciate that the use of molecules as a memory element or sensor greatly simplifies fabrication of such devices. The process of attaching molecules 44 can be performed in a simple laboratory hood instead of requiring an expensive semiconductor cleanroom. Further, since a small physical area may contain a relatively large number of bonded molecules, devices in accordance with the present invention are reduced in size relative to alternative technologies.

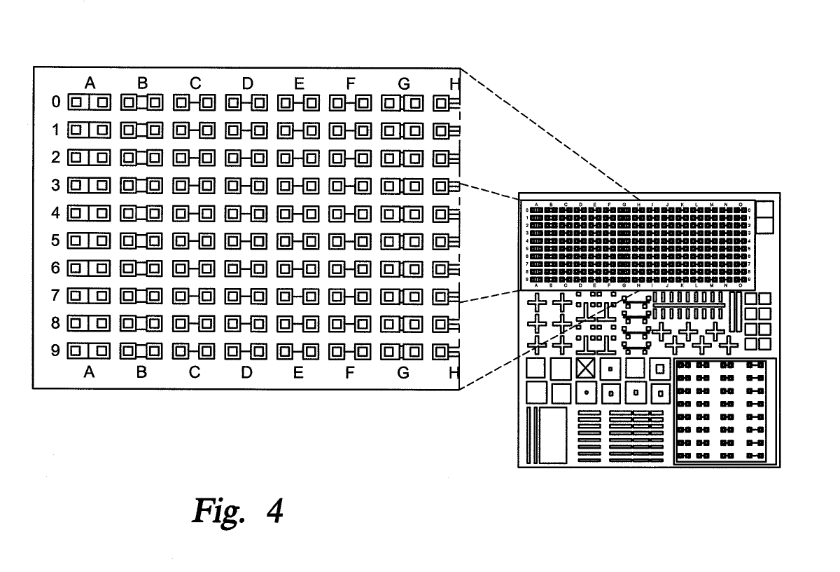

FIG. 4 shows an example of some exemplary mole-FET devices fabricated on a six-inch SOI wafer. Each wafer has approximately 190 die sites. On each die, there are approximately 150 mole-FET devices covering systematic variations of channel length, channel width, width/length ratio, and parameters related to the area of grafted molecules, such as area length, area width, overlap, and so on. Experimentally, devices have been fabricated with channels as small as 1 μm long and 1 μm wide and as large as 100 μm long and 100 μm wide, although the present invention is in no sense limited to channels and other design parameters within such specified ranges. Variations in substrate types (p-type or n-type), doping levels, channel silicon thickness, gate oxide thickness, and so on, are also contemplated as falling within the scope of the invention.

The programming of some types of non-volatile memory, such as flash memory, require the use of a relatively high voltage (>10 volts), which limits lifetime. The programming voltage of devices such as device 10 described herein has been experimentally proven to be less than 5 volts. Furthermore, as the devices are made smaller, the application voltages will decrease. Likewise, as the devices become smaller, the surface area to volume of the channels becomes greater, therefore the electronic impact of the grafted molecules should be more profound on smaller devices.

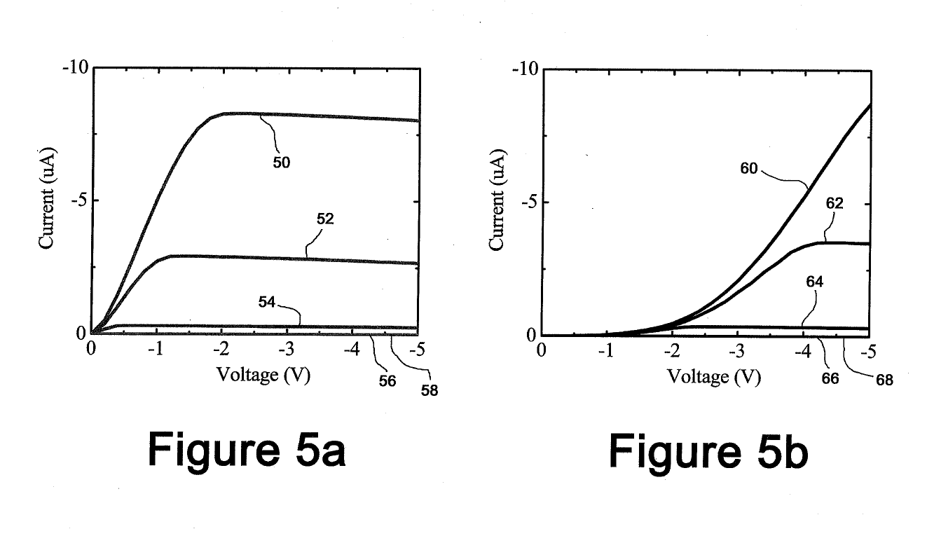

With mole-FET devices such as have thus far been described herein, the effects. of the grafting of molecules 44 to gate regions 40 and 42 can be clearly observed. Referring to FIG. 5a, there is shown a device 10 fabricated as described above and having molecules such that shown in FIG. 3g grafted onto channel region 42. A well defined transistor output characteristic (I-V curve) can be clearly observed. In particular, shown in FIG. 5a are the I-V curves corresponding to gate voltages of −20V (curve 50), −15V (curve 52), −10V (curve 54), −5V (curve 56), and 0V (curve 58).

Molecules 44 were then removed from the experimental device, through 15 minutes of exposure to UV ozone treatment, which destroys the molecules 44 but has little effect on the device's inorganic base structure, other than creating a surface oxide. FIG. 5b shows the performance of the resultant molecule-free device, for gate voltages of −20V (I-V curve 60), −15V (curve 62), −10V (curve 64), −5V (curve 66), and 0V (curve 68).

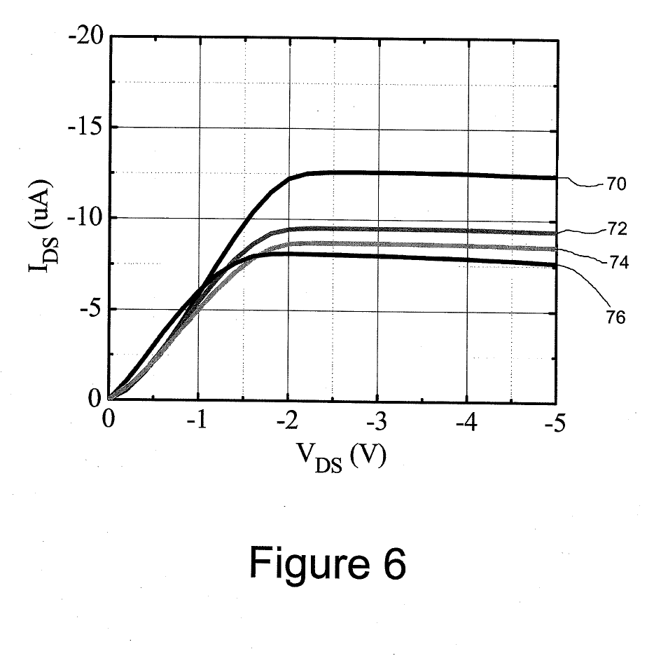

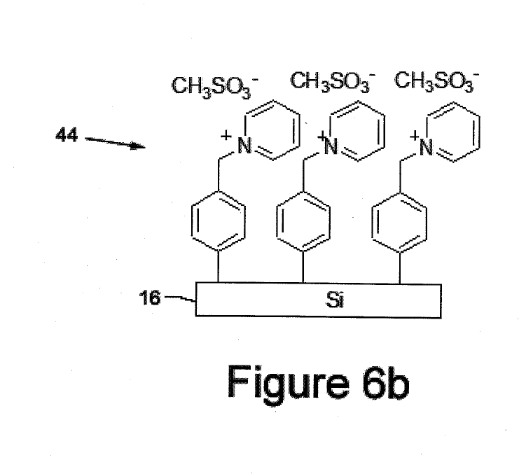

Those of ordinary skill in the art having the benefit of the present disclosure can further appreciate the effect of the grafted molecules 44 though observation of the relationship of channel current to molecule area. Referring to FIG. 6, at a constant gate voltage of −20V, the I-V characteristics of five transistors which are identical except for the area for molecule grafting is varied.

In each case in FIG. 6, the molecule layer 44 is a molecular monolayer as shown in FIG. 6b, which is formed using the diazonium salt from FIG. 3h, resulting in the grafting of benzyl alcohol to silicon substrate 16, followed by further treatment with methanesulfonyl chloride (CH₃SO₂Cl) and pyridine to form the layer 44 shown in FIG. 6b. While the area of the channel remains the same, the nominal molecule-grafted area upon the channel varies from 85×85 μm² (I-V curve 70 in FIG. 6), to 60×60 μm² (I-V curve 72), to 35×35 μm² (I-V curve 74), to 20×20 μm² (I-V curve 76). As can be seen in FIG. 6, the channel current decreases steadily with decreasing molecule-grafted area. Since all other design parameters are the same, including channel size, this effect must be credited to the molecular effect of molecules 44.

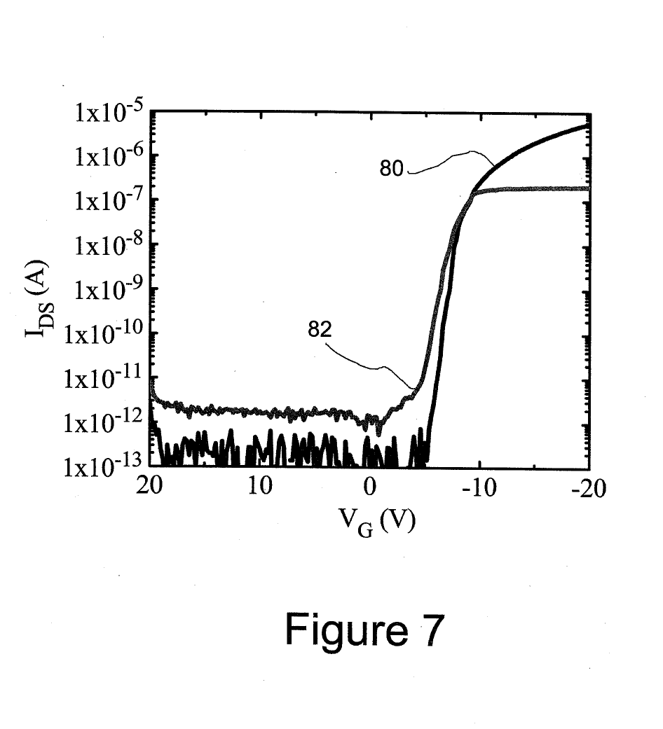

The influence of molecular monolayer 44 is also shown through observation of gating effects. As shown in FIG. 7, a device 10 in accordance with the presently disclosed embodiment of the invention, using molecules as shown in FIG. 3g, was tested with a source-drain voltage of −1.5 V, resulting in the I-V curve 80. Then, molecular monolayer 44 was removed using 15 minutes of UV ozone treatment, removing grafted molecules 44 but introducing little change to the backbone transistor structure. Further testing resulted in the I-V curve designated with reference numeral 82 in FIG. 7. As would be appreciated by those of ordinary skill in the art, there are clear differences in corresponding gating characteristics. Firstly, the saturation channel current for the molecule-bearing device is much larger than that of the molecule-absent transistor (approximately two orders of magnitude). Therefore, the molecule-bearing device has a much larger on/off ratio. Secondly, the sub-threshold swing for the molecule-bearing device is better than the molecule-absent device.

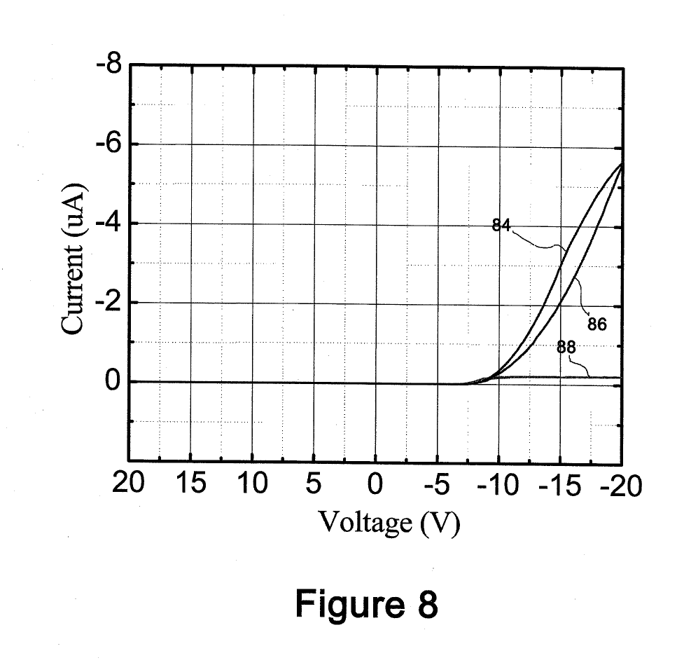

A further example illustrating the effects of grafting molecules 44 onto the gate region (40 or 42) of the device of FIG. 1 is shown in FIG. 8, which uses molecules 44 corresponding to those shown in FIG. 6b. As shown in FIG. 8, in the presence of grafted molecules 44, channel current increases significantly (I-V curves 84 and 86 in FIG. 8) as compared with that where molecules 44 are not present (I-V curve 88 in FIG. 8). Note that 86 is the forward sweep direction (0 to −20 V) and 84 is the backward sweep direction (−20 to 0) for the molecule-grafted device. Clearly, the grafting of molecules 44 exerts significant influences on the device's input and output characteristics.

The hysteresis effect observable between curves 84 (voltage scanning down) and 86 (voltage scanning up) in FIG. 8 (falling voltage versus rising voltage) indicates a memory effect. It is contemplated that such hysteresis can be increased, possibly leading to a non-volatile memory.

In an alternative embodiment of the invention, a conductive layer of silicon or other material is placed in the silicon under the transistor to serve as the gate instead of locating it on the backside. This allows easier programming of individual devices. Also regular silicon wafers can be used in place of SOI wafers.

Furthermore, a traditional MOS transistor structure can be used if the gate oxide is removed by an etching process, allowing molecules to attach to the silicon under the gate.

A traditional MOS transistor structure could be used and an opening could be made to the gate. Molecules would then assemble directly to the top of the gate.

From the foregoing description of particular embodiments of the invention, it should be apparent that a hybrid molecular electronic device has been disclosed which may be operable as switching, memory, and/or sensor device has been disclosed which offers significant and unique properties over present technologies. Although a broad range of implementation details have been discussed herein, these are not to be taken as limitations as to the range and scope of the present invention as defined by the appended claims. A broad range of implementation-specific variations and alterations from the disclosed embodiments, whether or not specifically mentioned herein, may be practiced without departing from the spirit and scope of the invention as defined in the appended claims.

For example, although specific techniques have been described herein for formation of the molecular monolayer 44 on the channel region of device 10, the present invention is in no sense limited to these specific techniques, and it is contemplated that various alternative methods may be employed to achieve the molecular modulation of device operation as described herein.

Furthermore, although the present invention has been described herein in the context of silicon devices, it is contemplated that the present invention may find applicability in the context of other materials, including, without limitation, gallium arsenide devices, as the molecular attachment chemistry is quite broad. Also, as noted above, it is contemplated that the invention is in no sense limited to devices in which the gating voltage is applied to the underside of the substrate, and that those of ordinary skill in the art having the benefit of the present disclosure would appreciate that more conventional field-effect transistor architectures may be adapted to achieve the benefits and results of the present invention.

Finally, although specific explanations as to how the presence of molecules 44 on the channel regions affects the conductive properties of the channels (oxidation and reduction of the molecules) have been presented herein, it is to be understood that such explanations are only the inventors' present best theoretical understanding of the electrochemical mechanisms involved, based upon empirical observations; it is not intended that the present invention be limited by the accuracy of such explanations. For example, it could be that the electrostatic potential of the molecules atop the channel affects the mobility within the channel.

What is claimed is:

1. A molecular field-effect transistor (FET) comprising molecules assembled on a silicon surface, said molecules responsive to a gate voltage to modify the source/drain current characteristics of said transistor.

2. A molecular FET in accordance with claim 1, wherein said substrate functions as a gate with a backside contact for receiving said gate voltage.

3. A molecular FET in accordance with claim 1, wherein said transistor is an n-channel transistor.

4. A molecular FET in accordance with claim 1, wherein said transistor is a p-channel transistor.

5. A molecular FET in accordance with claim 1, wherein said transistor is an enhancement mode transistor.

6. A molecular FET in accordance with claim 1, wherein said transistor is a depletion mode transistor.

7. A molecular FET in accordance with claim 1, wherein said transistor functions as a memory element.

8. A molecular FET in accordance with claim 1, wherein said transistor functions as a chemical sensor.

9. A molecular FET comprising a MOS transistor having gate oxide removed and molecules assembled onto the silicon under the gate.

10. A molecular FET in accordance with claim 9, further having an opening placed on top of the gate, where molecules can be assembled.

11. A hybrid molecular electronic device, comprising:
a silicon-on-insulator substrate comprising a bottom silicon substrate, an intermediate insulating layer, and a top silicon substrate;
a metallization layer formed on a bottom surface of said bottom silicon substrate;
first and second doped regions formed on a top surface of said top silicon substrate, said first and second regions being spaced apart so as to form a channel region therebetween; and
a molecular layer, grafted onto said channel region between said first and second doped regions;
wherein a gate voltage applied to said metallization layer controls conductivity between said first and second doped regions.

12. A hybrid molecular electronic device in accordance with claim 11, wherein said molecular layer comprises a molecular monolayer.

13. A hybrid molecular electronic device in accordance with claim 12, wherein said molecular monolayer is covalently bound to said channel region.

14. A hybrid molecular electronic device in accordance with claim 11, wherein said top substrate is p-type silicon and said first and second doped regions are n+ regions.

15. A hybrid molecular electronic device in accordance with claim 14, further comprising a third doped region in said channel region.

16. A hybrid molecular electronic device in accordance with claim 15, wherein said third doped region comprises doping limited to the surface of said substrate.

17. A hybrid molecular electronic device in accordance with claim 15, wherein said third doped region is an n− region.

18. A hybrid molecular electronic device in accordance with claim 11, wherein application of a gate voltage to said metallization layer decreases electrical conductivity across said channel region between said first and second doped regions.

19. A hybrid molecular electronic device in accordance with claim 11, wherein application of a gate voltage to said metallization layer modifies electrical conductivity across said channel region between said first and second doped regions.

20. A hybrid molecular electronic device in accordance with claim 11, wherein molecules in said molecular layer are selectively reactive with target molecules.

21. A hybrid molecular electronic device in accordance with claim 20, wherein reaction of molecules in said molecular layer with target molecules causes a change in electrical conductivity across said channel region between said first and second doped regions.

22. A hybrid molecular electronic device in accordance with claim 11, further comprising:
first and second metallic contacts respectively disposed on said first and second doped regions.

23. A hybrid molecular electronic device in accordance with claim 21, wherein said molecular layer comprises a layer of saccharide molecules.

24. A hybrid molecular electronic device in accordance with claim 21, wherein said molecular layer comprises a layer of peptide molecules.

25. A hybrid molecular electronic device in accordance with claim 21, wherein said molecular layer comprises a layer of oligonucleotides.

26. A hybrid molecular electronic device in accordance with claim 21, wherein said molecular layer comprises a layer of biotin.

27. A method of fabricating a hybrid molecular electronic device, comprising:
providing a substrate;
forming first and second doped regions on an upper surface of said substrate, thereby defining a channel region between said first and second doped regions; and
grafting a layer of molecules onto said upper surface of said substrate in said channel region.

28. A method in accordance with claim 27, wherein said step of grafting a layer of molecules is performed at open circuit potential.

29. A method in accordance with claim 27, wherein said layer of molecules comprises a monolayer of molecules.

30. A method in accordance with claim 27, further comprising, prior to said step of grafting a layer of molecules:
forming a third doped region in said channel region.

31. A method in accordance with claim 28, wherein said step of forming a third doped region comprises surface doping said upper surface of said substrate.

32. A method in accordance with claim 27, further comprising:
forming a gate electrode on said substrate.

33. A method in accordance with claim 32, wherein said gate electrode is formed on an underside of said substrate.

34. A method in accordance with claim 27, wherein said substrate comprises a silicon-on-insulator substrate.

35. A molecular electronic field effect transistor, comprising:
a substrate;
first and second doped regions formed on a top surface of said substrate, said first and second regions being spaced apart so as to form a channel region therebetween; and
a molecular layer, grafted onto said channel region between said first and second doped regions;
wherein a gate voltage applied to a gate electrode of said device controls conductivity between said first and second doped regions.

36. A molecular electronic field effect transistor in accordance with claim 35, wherein said molecular layer comprises a molecular monolayer.

37. A molecular electronic field effect transistor in accordance with claim 36, wherein said molecular monolayer is covalently bound to said channel region.

38. A molecular electronic field effect transistor in accordance with claim 35, wherein said substrate is p-type silicon and said first and second doped regions are n+ regions.

39. A molecular electronic field effect transistor in accordance with claim 39, further comprising a third doped region in said channel region.

40. A molecular electronic field effect transistor in accordance with claim 39, wherein said third doped region comprises doping limited to the surface of said substrate.

41. A molecular electronic field effect transistor in accordance with claim 39, wherein said third doped region is an n− region.

42. A molecular electronic field effect transistor in accordance with claim 34, wherein application of a gate voltage to said gate electrode decreases electrical conductivity across said channel region between said first and second doped regions.

43. A hybrid molecular electronic device in accordance with claim 34, wherein application of a gate voltage to said gate electrode increases electrical conductivity across said channel region between said first and second doped regions.

44. A hybrid molecular electronic memory device, comprising:
a substrate;
first and second doped regions formed on a top surface of said substrate, said first and second regions being spaced apart so as to form a channel region therebetween; and
a molecular layer, grafted onto said channel region between said first and second doped regions;
wherein a gate voltage applied to said metallization layer controls degrees of conductivity between said first and second doped regions.

45. A hybrid molecular electronic memory device in accordance with claim 44, wherein a first degree of conductivity between said first and second doped regions represents a first memory state, and a second degree of conductivity between said first and second doped regions represents a second memory state.

46. A hybrid molecular electronic memory device in accordance with claim 44, wherein said molecular layer comprises a molecular monolayer.

47. A hybrid molecular electronic memory device in accordance with claim 45, wherein said molecular monolayer is covalently bound to said channel region.

48. A hybrid molecular electronic memory device in accordance with claim 44, wherein said substrate is p-type silicon and said first and second doped regions are n+ regions.

49. A hybrid molecular electronic memory device in accordance with claim 45, further comprising a third doped region in said channel region.

50. A hybrid molecular electronic memory device in accordance with claim 49, wherein said third doped region comprises doping limited to the surface of said substrate.

51. A hybrid molecular electronic memory device in accordance with claim 50, wherein said third doped region is an n− region.

52. A hybrid molecular electronic memory device in accordance with claim 44, wherein application of a gate voltage to said metallization layer decreases electrical conductivity across said channel region between said first and second doped regions.

53. A hybrid molecular electronic memory device in accordance with claim 44, wherein application of a gate voltage to said metallization layer increases electrical conductivity across said channel region between said first and second doped regions.

54. A hybrid molecular electronic device in accordance with claim 44, further comprising:
first and second metallic contacts respectively disposed on said first and second doped regions.

55. A method of modifying conductivity properties of a field-effect transistor having a channel region disposed between a source region and an drain region formed in a substrate, comprising:
grafting a layer of molecules over said channel region.

56. A method in accordance with claim 55, wherein said substrate comprises a silicon substrate.

57. A method in accordance with claim 55, wherein said layer of molecules comprises a monolayer of molecules covalently bonded to said substrate.

58. A method in accordance with claim 57, wherein said layer of molecules comprises a monolayer of molecules covalently bonded to said substrate over said channel region.

59. A method in accordance with claim 55, wherein said layer of molecules is grafted over said channel region under open circuit potential conditions.
